(19) United States
(12) Patent Application Publication
(10) Pub. No.: US 2024/0055409 A1
(43) Pub. Date: Feb. 15, 2024

(54) SEMICONDUCTOR DEVICE AND METHOD FOR FORMING SAME

(71) Applicant: Kaimin LV, Hefei (CN)

(72) Inventor: Kaimin LV, Hefei (CN)

(21) Appl. No.: 18/451,873

(22) Filed: Aug. 18, 2023

Related U.S. Application Data
(63) Continuation of application No. PCT/CN2022/118620, filed on Sep. 14, 2022.

(30) Foreign Application Priority Data
Aug. 15, 2022 (CN) 202210977432.2

(51) Int. Cl. H01L 25/065; H01L 23/00; H01L 23/48; H01L 23/31; H01L 25/00; H01L 21/768

(52) U.S. Cl. CPC H01L 25/0657; H01L 24/08; H01L 23/481; H01L 24/32; H01L 24/48; H01L 24/73; H01L 23/3128; H01L 25/50; H01L 24/80; H01L 21/76898; H01L 24/92; H01L 2224/08145; H01L 2224/32225; H01L 2224/48227; H01L 2224/73265; H01L 2224/80895; H01L 2224/80896; H01L 2224/92247

(57) ABSTRACT

Provided are a semiconductor device and a method for manufacturing the same. The semiconductor device includes a base and a plurality of semiconductor die sets located on a surface of the base and stacked in sequence along a first direction. The plurality of the semiconductor die sets are respectively connected to different ranks, and the plurality of semiconductor die sets are all electrically connected to the base. The first direction is a thickness direction of the base. Each of the semiconductor die sets includes a first die and a second die bonded face-to-face. The first die and the second die are connected to a same rank.

### CROSS-REFERENCE TO RELATED APPLICATION

The application is a continuation application of International Application PCT/CN2022/118620, filed on Sep. 14, 2022, which claims priority to Chinese Patent Application No. 202210977432.2, filed on Aug. 15, 2022. The disclosures of International Application No. PCT/CN2022/118620 and Chinese Patent Application No. 202210977432.2 are hereby incorporated by reference in their entireties.

### BACKGROUND

A semiconductor stack structure usually includes a plurality of dies. In related art, in order to realize the interconnection between all stacked dies and the base, it is necessary to bond wires on each layer of the dies. Because the heights of the dies of different layers are different, the lengths and the heights of gold wires connecting dies of different layers are different, which will lead to the problem of time delay.

In the related art, winding compensation is carried out inside or outside the dies, so that the times and phases of the dies connected to a same rank in the signal transmission process are as consistent as possible. However, this will cause the dies to be too large or lead to signal interference when the base is wound, and meanwhile more dies are prevented from stacking, resulting in hindering the improvement of the integration and the capacity of the semiconductor stacking structure.

### SUMMARY

The disclosure relates to the technical field of semiconductors, and in particular to a semiconductor device and a method for forming the same.

In view of this, embodiments of the disclosure provide a semiconductor device and a method of forming the same.

In the first aspect, the embodiments of the disclosure provide a semiconductor device, including a base and a plurality of semiconductor die sets.

The plurality of semiconductor die sets are located on a surface of the base and stacked in sequence along a first direction. The plurality of semiconductor die sets are respectively connected to different ranks, and the plurality of semiconductor die sets are all electrically connected to the base. The first direction is a thickness direction of the base.

Each of the plurality of semiconductor die sets includes a first die and a second die bonded face-to-face, and the first die and the second die are connected to a same rank.

In the second aspect, the embodiments of the disclosure provide a method for forming a semiconductor device, including the following operations.

A base is provided.

A plurality of semiconductor die sets stacked in sequence along a first direction are formed on a surface of the base. The plurality of semiconductor die sets are respectively connected to different ranks, and the plurality of semiconductor die sets are all electrically connected to the base. The first direction is a thickness direction of the base. Each of the semiconductor die sets includes a first die and a second die bonded face-to-face. The first die and the second die are connected to a same rank.

### BRIEF DESCRIPTION OF THE DRAWINGS

In the accompany drawings (which are not necessarily drawn to scale), similar reference numerals may describe similar components in different views. Similar reference numerals with different letter suffixes may denote different examples of similar components. The accompanying drawings generally illustrate, by way of examples, not limitation, various embodiments discussed herein.

FIG. 1 is a scheme structural diagram of a semiconductor device provided by an embodiment of the disclosure.

FIG. 2A and FIG. 2B are scheme structural diagrams of another semiconductor device provided by another embodiment of the disclosure.

FIG. 3 is a flowchart showing a method for forming a semiconductor device provided by an embodiment of the disclosure.

FIGS. 4A to 4H are schematic diagrams of structures during a process for forming a semiconductor device provided by an embodiment of the disclosure.

FIG. 5 is a flowchart showing a method for forming the semiconductor die sets provided by an embodiment of the disclosure.

### DETAILED DESCRIPTION

Exemplary embodiments of the disclosure will be described in more detail below with reference to the accompanying drawings. Although the exemplary embodiments of the disclosure are shown in the accompanying drawings, it is to be understood that the disclosure may be implemented in various forms and should not be limited by the specific embodiments set forth herein. On the contrary, these embodiments are provided to enable a more thorough understanding of the disclosure and to fully convey the scope of the disclosure to those skilled in the art.

In the following description, numerous specific details are given to provide a more thorough understanding of the disclosure. However, it will be apparent to those skilled in the art that the disclosure may be practiced without one or more of these details. In other examples, some technical features well known in the art are not described in order to avoid confusion with the disclosure, that is, not all features of the actual embodiments are described herein and well-known functions and structures are not described in detail.

In the drawings, the dimensions of layers, regions, elements and their relative dimensions may be exaggerated for clarity. The same reference numerals denote the same elements throughout.

It should be understood that when an element or layer is referred to as “above”, “adjacent to”, “connected to” or “coupled to” another element or layer, it may be directly above, adjacent to, connected to, or coupled to the other element or layer, or there may be an intermediate element or layer therebetween. Conversely, when an element is referred to as “directly above”, “directly adjacent to”, “directly connected to” or “directly coupled to” another element or layer, there is no intermediate element or layer therebetween. It should be understood that, although the terms first, second, third, etc. may be used to describe various elements, components, regions, layers, and/or portions, the elements, components, regions, layers, and/or portions should not be limited by these terms. These terms are used only to distinguish one element, component, region, layer, or portion from another element, component, region, layer, or portion. Therefore, a first element, component, region, layer, or portion discussed below may be expressed as a second element, component, region, layer, or portion without departing from the teachings of the disclosure. While discussing a second element, component, region, layer or portion, it does not imply that a first element, component, region, layer or portion is necessarily present in the disclosure.

The terms used herein are intended to describe specific embodiments only and are not to be a limitation of the disclosure. As used herein, the singular forms of “a/an”, “one” and “said/the” are also intended to include the plural forms, unless the context clearly indicates otherwise. It should also be understood that the terms “composed of/consist of” and/or “comprise/include”, when used in this specification, mean that the stated features, integers, steps, operations, elements and/or components are present, but do not exclude the presence or addition of one or more other features, integers, steps, operations, elements, components and/or groups. As used herein, the term “and/or” includes any of the listed items and all combinations thereof.

In embodiments of the disclosure, a first direction is the thickness direction of base. Any direction in a plane on which the base is located is defined as a second direction. The first direction is perpendicular to the second direction. For example, the first direction may be the X-axis direction in FIG. 1, and the second direction may be the Y-axis direction in FIG. 1.

An embodiment of the disclosure provides a semiconductor device. FIG. 1 is a scheme structural diagram of a semiconductor device provided by the embodiment of the disclosure. As shown in FIG. 1, the semiconductor device 100 includes: a base 10 and a plurality of semiconductor die sets located on a surface of base 10 and stacked in sequence along the X-axis direction. The plurality of semiconductor die sets are respectively connected to different ranks (not shown in FIG. 1), and the plurality of semiconductor die sets are all electrically connected to the base 10. Each of the plurality of the semiconductor die sets includes a first die and a second die bonded face-to-face, and the first die and the second die are connected to a same rank.

In the embodiment of the disclosure, the plurality of semiconductor die sets are respectively connected to different ranks, that is, a first semiconductor die set is connected to Rank0, a second semiconductor die set is connected to Rank1, a third semiconductor die set is connected to Rank2, and so on.

In some embodiments, each of the first die and the second die includes a front face and a back surface opposite to the front surface. Generally, the front face of the first die and the front face of the second die are provided with functional devices, interconnection wires or circuits.

In the embodiment of the disclosure, a bonding way of the first die and the second die in each of the plurality of the semiconductor die sets is face-to-face bonding, which means that the front surface of the first die set is bonded with the front surface of the second die in the semiconductor die set.

In the embodiment of the disclosure, the first die and the second die may be a dynamic random access memory (DRAM) die, a static random access memory (SRAM) die, a phase-change memory (PCM) die, an NAND Flash die or a Nor Flash die. In the embodiment of the disclosure, the first die and the second die are connected to a same rank, that is, the first die and the second die are both connected to Rank0 or Rank1.

Continuously referring to FIG. 1, the semiconductor device 100 includes two semiconductor die sets stacked in sequence along the X-axis direction, which are the semiconductor die set 131 and the semiconductor die set 132 respectively. The semiconductor die set 131 includes a first die (die1) and a second die (die2); and the first die (die1) and the second die (die2) are bonded face-to-face. The semiconductor die set 132 includes a first die (die3) and a second die (die4); and the first die (die3) and the second die (die4) are face-to-face bonded.

In the embodiment of the disclosure, the first die (die1) and the second die (die2) of the semiconductor die set 131 are connected to a same rank (Rank0). The first die (die3) and the second die (die4) of the semiconductor die set 132 are connected to a same rank (Rank 1).

In some embodiments, continuously referring to FIG. 1, the semiconductor device 100 also includes connection structures. The connection structures are configured to connect the base 10 with the semiconductor die sets. For example, the connection structure 191 is configured to connect the base 10 with the semiconductor die set 131, and the connection structure 192 is configured to connect the base 10 with the semiconductor die set 132.

In some embodiments, the connection structures may be one of gold wire, silver wire, copper wire, aluminum wire or alloy wire.

In some embodiments, there may be one or more connection structure between each of the semiconductor die sets and the base. Different connection structures are configured to transmit different signals. Continuously referring to FIG. 1, the semiconductor device 100 further includes a connection structure 193 and a connection structure 194. The connection structure 193 is configured to connect the base 10 with the semiconductor die set 132. The connection structure 193 and the connection structure 192 transmit different signals. For example, the connection structure 193 transmits low signal DQO-7 and the connection structures 192 transmits high signal DQ8-15. The connection structure 194 is configured to connect the base 10 and the semiconductor die set 131. The connection structure 194 and the connection structure 191 transmit different signals. For example, the connection structure 194 transmits low signal DQO-7 and the connection structure 191 transmits high signal DQ8-15.

In some embodiments, continuously referring to FIG. 1, the semiconductor device 100 further includes an insulating layer 133 between the semiconductor die set 131 and the base 10, and a dielectric layer 134 located between the semiconductor die set 131 and the semiconductor die set 132 adjacent to each other. The insulating layer 133 may be a die attach film (DAF), and the dielectric layer 134 may be a film over wire (FOW).

In another embodiment, the insulating layer 133 may also be a FOW film, or another non-conductive film, or non-conductive adhesive. The dielectric layer 134 may also be a DAF film, or another non-conductive film, non-conductive adhesive, a conductive film, or a conductive adhesive.

In the embodiments of the disclosure, since the semiconductor dies will generate a lot of heat during an operation process, the dielectric layer and the insulating layer may at least be configured to ameliorate the warpage phenomenon of the semiconductor dies.

The semiconductor device provided by the embodiments of the disclosure includes a plurality of semiconductor die sets electrically connected to the base, and each of the semiconductor die sets includes a first die and a second die bonded face-to-face. Since the first die and the second die are connected to a same rank, the signal transmission times and phases of the first die and the second die can be consistent, and the performance of the semiconductor device can be improved. In addition, in the embodiments of the disclosure, winding is not required when the semiconductor die set (i.e., the first die and the second base) is electrically connected to the base, so that the number of stacking layers of the semiconductor device can be increased, and thus the integration density of the semiconductor device can be improved.

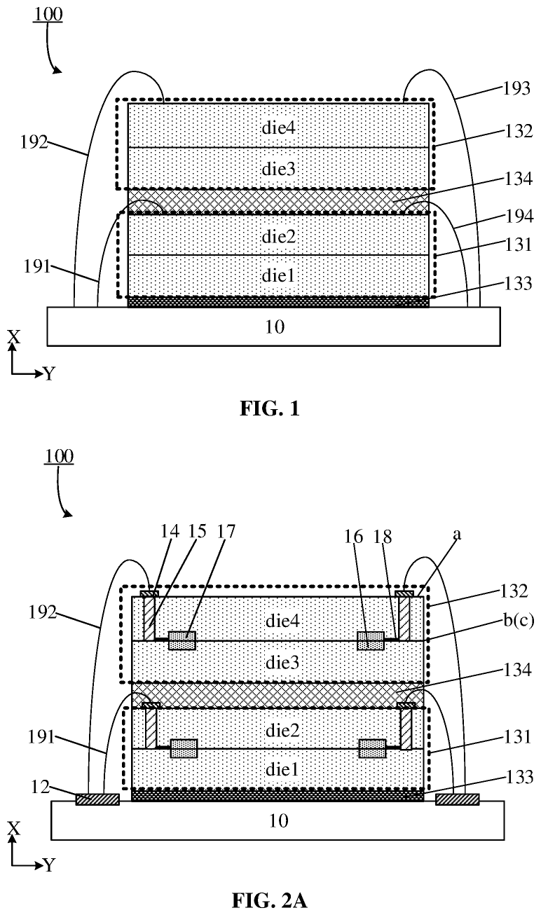

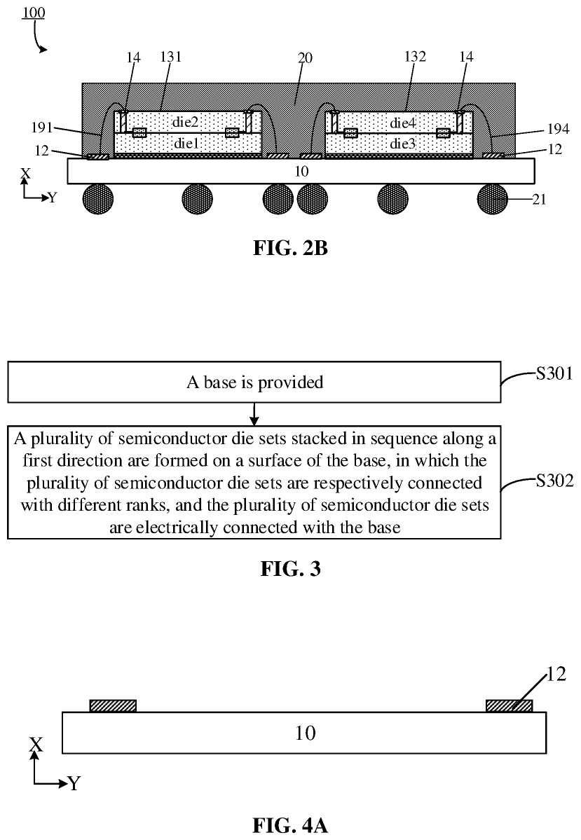

FIG. 2A is a scheme structural diagram of another semiconductor device provided by an embodiment of the disclosure. As shown in FIG. 2A, the semiconductor device 100 includes a base 10 and a plurality of semiconductor die sets located on a surface of the base 10 and stacked in sequence along the X-axis direction. The plurality of semiconductor die sets are respectively connected to different ranks (not shown in FIG. 2A), and the plurality of semiconductor die sets are all electrically connected to the base 10. Each of the semiconductor die sets includes a first die and a second die bonded face-to-face, and the first die and the second die are connected to a same rank.

In the embodiment of the disclosure, continuously referring to FIG. 2A, the semiconductor device 100 includes a semiconductor die set 131 and a semiconductor die set 132 stacked in sequence along the X axis. In another embodiment, the number of the plurality of semiconductor die sets stacked in sequence along the X axis may also be 3, 4, 5 or more.

Continuously referring to FIG. 2A, the semiconductor die set 131 includes a first die (die1) and a second die (die2), and the semiconductor die set 132 includes a first die (die3) and a second die (die4). The first die (die1) and the second die (die2) of the semiconductor die set 131 are connected to a same rank (Rank0). The first die (die3) and the second die (die4) of the semiconductor die set 132 are connected to a same rank (Rank 1).

In some embodiments, continuously referring to FIG. 2A, each of the first dies includes a plurality of first bond pads 16 arranged at intervals, and the plurality of the first bond pads 16 are located on a third surface C of the first die away from the base 10 along the X-axis direction. Each of the second dies includes a plurality of second bond pads 17 arranged at intervals, and the plurality of the second bond pads 17 are located on a second surface B of the second die close to the base 10 along the X-axis direction. A projection area of each of the first bond pads 16 coincides with a projection area of a corresponding one of the second bond pads 17 along the X-axis direction, and each of the first bond pads 16 is electrically connected to the corresponding one of the second bond pads 17.

In the embodiment of the disclosure, the first bond pads 16 and the second bond pads 17 may be copper (Cu) pads or other conductive metal pads, such as aluminum (Al) pads, gold (Au) pads, tungsten (W) pads, or the like.

In the embodiment of the disclosure, the first die (die1) and the second die (die2) in the semiconductor die set 131 are bonded face-to-face through the first bond pads 16 and the second bond pads 17, and the first die (die3) and the second die (die4) in the semiconductor die set 132 are bonded face-to-face through the first bond pads 16 and the second bond pads 17, such that the electrical connection between the first die die1 and the second die die2 and the electrical connection between the first die die3 and the second die die4 can be achieved.

In some embodiments, continuously referring to FIG. 2A, the semiconductor device 100 further includes first connection pads 14, and each of the second dies (such as die4) includes conductive pillars 15. The first connection pads 14 are electrically connected to the conductive pillars 15. The first connection pads 14 are located on a first surface A of the second die (die4) away from the base 10 along the X-axis direction, and the conductive pillars 15 penetrate through the second die (die4).

It is to be noted that in the embodiment of the disclosure, the number of the conductive pillars 15 is the same as the number of the second bond pads 17. In implementation, any number of the second bond pads 17 may be provided as needed, and the number of the conductive pillars 15 is provided according to the number of the second bond pads 17. In addition, in the embodiment of the disclosure, the number of the first connection pads 14 is the same as that of the conductive pillars 15. In implementation, it is necessary to provide one first connection pad 14 corresponding to each of the conductive pillars 15.

Alternatively, it is to be noted that in the embodiment of the disclosure, the number of the conductive pillars 15 is different from the number of the second bond pads 17. In implementation, any number of the second bond pads 17 may be provided as needed, different second bond pads 17 may be electrically connected to each other; and the number of the conductive pillars 15 is provided according to the number of the connected second bond pads 17, and the number of the conductive pillars 15 is less than the number of the second bond pads 17.

In the embodiment of the disclosure, the first connection pads 14 are disposed at edges of each of the semiconductor die sets in order to facilitate leading out signals of the semiconductor die sets. The first connection pads 14 may be aluminum pads, tin pads or gold-tin pads, or the like. The conductive pillars 15 may be composed of any one or more conductive metallic materials, such as tungsten, cobalt (Co), copper, aluminum and other metals or alloys. A metal or non-metal barrier layer (e.g. titanium nitride) may be provided at a contact area between each of the conductive pillars 15 and the die, and a buffer layer (e.g. silicon oxide) may also be provided.

In the embodiment of the disclosure, the conductive pillars are disposed vertically. Therefore, on the one hand, the interconnection length between the dies can be reduced, the signal delay can be reduced and the signal transmission speed can be improved; on the other hand, the integration of semiconductor stack structure can be improved.

In some embodiments, continuously referring to FIG. 2A, the second die (die4) further includes re-distributed layers (RDL) 18 located on the second surface B. The re-distributed layers 18 are configured to connect the second bond pads 17 with the conductive pillars 15. The re-distributed layers 18 may be composed of any one or more conductive metallic materials, such as copper, aluminum, copper-aluminum alloy or tungsten.

In some embodiments, continuously referring to FIG. 2A, the semiconductor device 100 further includes second connection pads 12 located on the surface of the base 10. Each of the semiconductor die sets is electrically connected to the base 10 through the first connection pads 14 and the second connection pads 12.

In some embodiments, the second connection pads 12 are gold fingers on the surface of the base 10.

In some embodiments, continuously referring to FIG. 2A, the semiconductor device 100 further includes connection structures for connecting the first connection pads 14 and the second connection pads 12. For example, the connection structures 191 are configured to connect the second connection pads 12 and the first connection pads 14 on the surface of the semiconductor die set 131. The connection structures 192 are configured to connect the second connection pads 12 and the first connection pads 14 on the surface of semiconductor die set 132. Each of the connection structures may be a filiform wire, a strip wire or the like of a metal or an alloy such as gold, silver, copper, aluminum or the like.

In some embodiments, continuously referring to FIG. 2A, two adjacent semiconductor die sets along the X-axis direction are isolated and adhered through a dielectric layer 134. The dielectric layer 134 may be a FOW film. Since the FOW film has a high hardness, the FOW film also serves to fix the connection structures 191 that are connected to the first connection pads 14 on the semiconductor die set 131 and prevent the connection structure 191 from shifting or falling off.

In some embodiments, continuously referring to FIG. 2A, the base 10 and the semiconductor die sets are isolated and adhered through an insulating layer 133. The insulating layer 133 may be a DAF film.

FIG. 2B is a scheme structural diagram of another semiconductor device provided by an embodiment of the disclosure. As shown in FIG. 2B, the semiconductor device 100 includes a base 10 and a plurality of semiconductor die sets located on a surface of the base 10 and arranged in sequence along an Y-axis direction. Each of the plurality of the semiconductor die sets is electrically connected to the base 10. Each of the plurality of the semiconductor die sets includes a first die and a second die bonded face-to-face, and the first die and the second die are connected to a same rank.

In the embodiment of the disclosure, continuously referring to FIG. 2B, the semiconductor device 100 includes a semiconductor die set 131 and a semiconductor die set 132 arranged in sequence along the Y axis. In another embodiment, the number of the plurality of semiconductor die sets arranged in sequence along the Y axis may also be 3, 4 or more.

In the embodiment of the disclosure, continuously referring to FIG. 2B, the semiconductor die set 131 includes a first die (die1) and a second die (die2), and the semiconductor die set 132 includes a first die (die3) and a second die (die4). The first die (die1) and the second die (die2) of the semiconductor die set 131 are connected to a same rank (Rank0). The first die (die3) and the second die (die4) of the semiconductor die set 132 are connected to a same rank (Rank 1).

It is to be noted that, in the semiconductor die sets arranged in sequence along the Y-axis direction of the embodiment of the disclosure, there may be a plurality of semiconductor die sets stacked along the X-axis direction on each of the semiconductor die sets arranged in sequence along the Y-axis direction.

In some embodiments, continuously referring to FIG. 2B, the semiconductor device 100 further includes first connection pads 14 located on the surfaces of the second dies (die2 and die4) away from the base 10 along the X-axis direction, and second connection pads 12 located on a side of the base 10 close to the semiconductor die set 131 (or the semiconductor die set 132). Each of the semiconductor die sets is electrically connected to the base 10 through the first connection pads 14 and the second connection pads 12.

In some embodiments, continuously referring to FIG. 2B, the semiconductor device 100 further includes connection structures 191 and connection structures 194. The connection structures 191 are configured to connect the first connection pads 14 with the second connection pads 12 in the semiconductor die set 131, and the connection structures 194 are configured to connect the first connection pads 14 with the second connection pads 12 in the semiconductor die set 132.

In some embodiments, continuously referring to FIG. 2B, the semiconductor device 100 further includes a plastic packaging layer 20 covering the semiconductor die set 131, the semiconductor die set 132 and the base 10. The plastic packaging layer 20 can serve a good protection and electromagnetic shielding, and can improve the overall performance of the semiconductor device 100. The material of the plastic packaging layer 20 may include a polyimide layer, a silica gel layer, an epoxy resin layer or a curable resin-based material layer.

It is to be noted that, the plastic packaging layer 20 covers not only the semiconductor die set 131, the semiconductor die set 132 and base 10, but also the connection structures and connection parts between the semiconductor die set 131, the semiconductor die set 132 and the base 10. For example, the plastic packaging layer 20 also covers the first connection pads 14, the second connection pads 12, the connection structures 191 and the connection structures 194.

In some embodiments, referring further to FIG. 2B, the base 10 further includes connection solder balls 21 located on a side of the base 10 away from the semiconductor die sets. The connection solder balls 21 and the second connection pads 12 are respectively located on two sides of the base 10 along the X-axis direction. The second connection pads 12 and the connection solder balls 21 are electrically connected through interconnection wires inside the base 10.

In some embodiments, the connection solder balls 21 may serve as input ends or output ends of electrical signals of the semiconductor device 100 and form an electrical connection relationship with an external device (e.g. a printed circuit board). The material of the connection solder balls 21 include one or a combination of two or more of tin, lead, gold, silver, copper, indium, bismuth, cadmium (Cd), zinc (Zn), lanthanide (La), silicon (Si), germanium (Ge), lithium (Li), phosphorus (P), nickel (Ni) and rare metals. The connection solder balls 21 may be formed by a ball-mount reflow process.

It is to be noted that, the semiconductor device in the embodiments of the disclosure is similar to the semiconductor devices in the foregoing embodiments. The technical features not disclosed in detail in the embodiments of the disclosure can be understood with reference to the above-mentioned embodiments, and the features are not repeated here.

The semiconductor device provided by the embodiments of the disclosure includes the plurality of semiconductor die sets electrically connected to the base, and each of the semiconductor die sets includes a first die and a second die bonded face-to-face. Since the first die and the second die are connected to a same rank, the signal transmission times and phases of the first die and the second die can be consistent, and the performance of the semiconductor device can be improved. In addition, in the embodiments of the disclosure, winding is not required when the semiconductor die set (i.e., the first die and the second base) is electrically connected to the base, so that the number of stacking layers of the semiconductor device can be increased and the integration density of the semiconductor device can be improved.

Embodiments of the disclosure further provide a method for forming a semiconductor device. FIG. 3 is a flowchart showing a method for forming a semiconductor device provided by an embodiment of the disclosure. As shown in FIG. 3, the method for forming a semiconductor device includes the following operations.

In S301, a base is provided.

In the embodiment of the disclosure, second connection pads are formed on a surface of the base along an X-axis direction, and connection solder balls are formed on another surface. The second connection pads are electrically connected to the connection solder balls through interconnection wires inside the base. The connection solder balls may serve as input ends or output ends of electrical signals of a semiconductor device and to form an electrical connection relationship with an external device.

In S302, a plurality of semiconductor die sets stacked in sequence along a first direction are formed on a surface of the base. The plurality of semiconductor die sets are respectively connected to different ranks, and the plurality of semiconductor die sets are all electrically connected to the base.

In the embodiment of the disclosure, each of the semiconductor die sets includes a first die and a second die bonded face-to-face, and the first die and the second die are connected to a same rank.

In some embodiments, the first die and the second die may be a DRAM die, a SRAM die, a PCM die, an NAND Flash die or a Nor Flash die. In the embodiment of the disclosure, the first die and the second die are connected to a same rank, that is, the first die and the second die are both connected to Rank0 or Rank1.

In the embodiment of the disclosure, the plurality of semiconductor die sets are respectively connected to different ranks, that it, a first semiconductor die set is connected to Rank0, a second semiconductor die set is connected to Rank1, a third semiconductor die set is connected to Rank2, and so on.

In some embodiments, the method for forming a semiconductor device may further include the following operations. The plurality of semiconductor die sets arranged in sequence along a second direction are formed on the surface of the base. The plurality of semiconductor die sets are all electrically connected to the base.

In some embodiments, the forming a plurality of semiconductor die sets stacked in sequence along a first direction on a surface of the base and, or the forming a plurality of semiconductor die sets arranged in sequence along a second direction on a surface of the base, includes the following two operations.

In a first operation, the plurality of the semiconductor die sets are formed.

In a second operation, the plurality of the semiconductor die sets are electrically connected to the base in sequence.

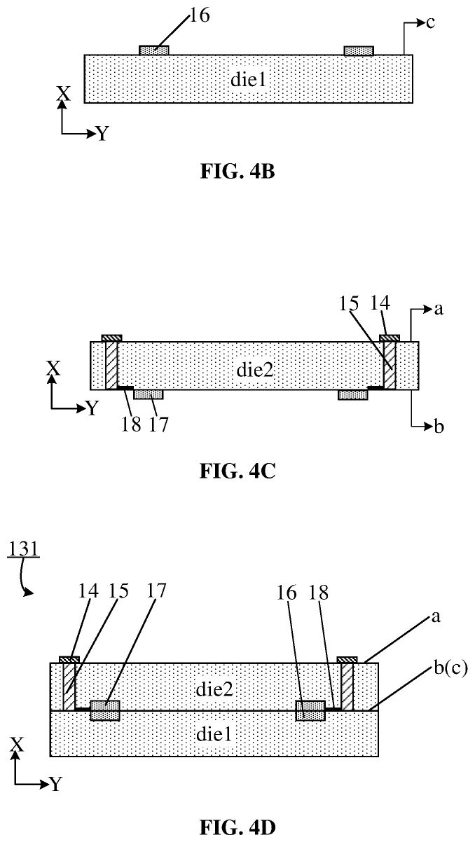

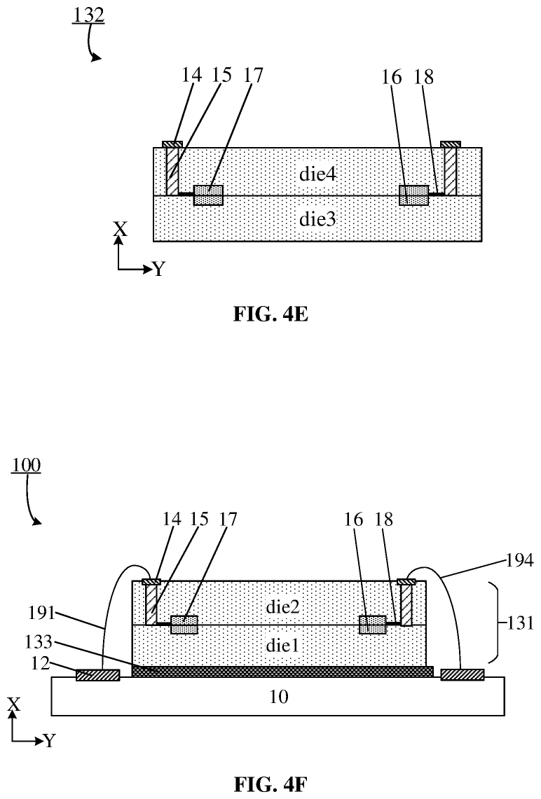

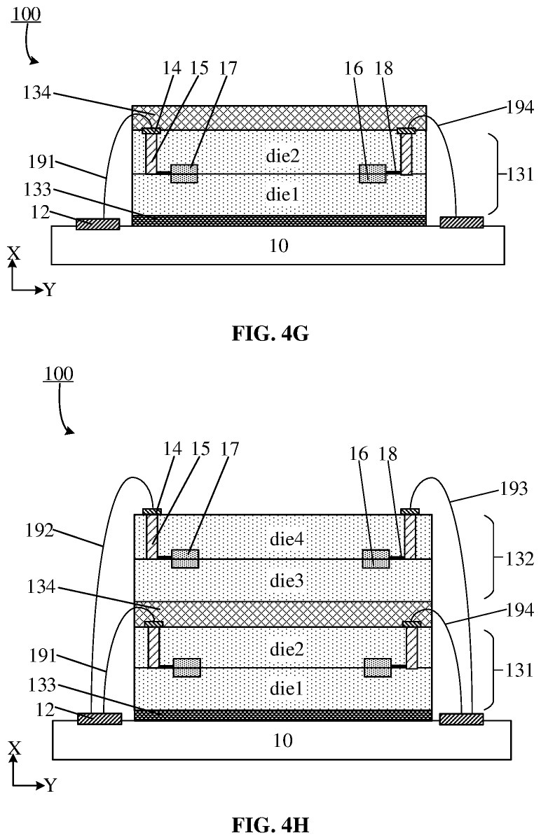

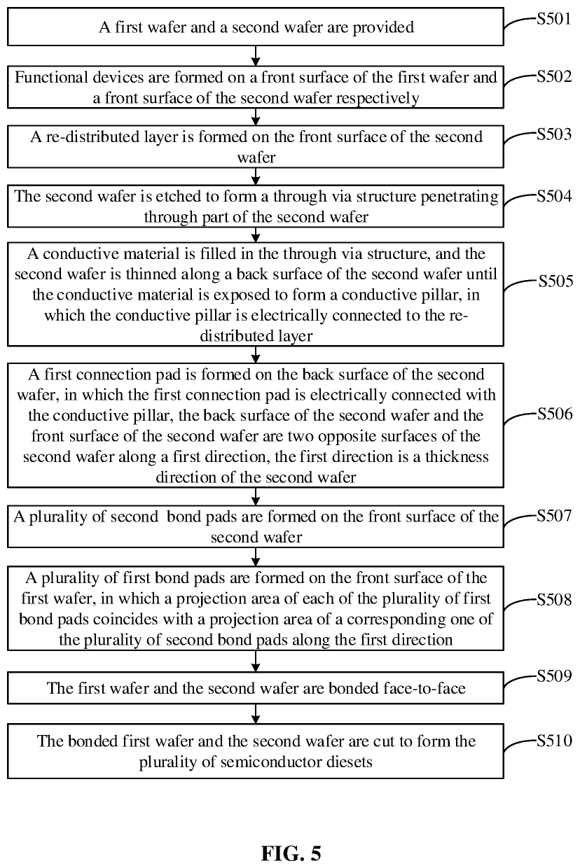

FIGS. 4A to 4H are schematic diagrams of structures during a process for forming a semiconductor device provided by an embodiment of the disclosure. Hereinafter, taking a semiconductor device including two semiconductor die sets stacked in sequence along the X-axis direction in the embodiment of the disclosure as an example, the process for forming the semiconductor device is described with reference to FIGS. 4A to 4H. FIGS. 4A to 4H are schematic diagrams of structures during the process for forming the semiconductor device provided by the embodiment of the disclosure in a cross-sectional view.

First, as shown in FIG. 4A, second connection pads 12 are formed on the base 10. The second connection pads 12 are gold fingers on the surface of the base 10.

In the embodiment of the disclosure, the plurality of semiconductor die sets are generally disposed at a central position on a surface of the base 10. The second connection pads 12 are generally disposed at peripheral edges of the base 10, and the second connection pads 12 are disposed outside a projection area of the plurality of semiconductor dies on the base 10. The number of the second connection pads 12 may be provided as needed. Different second connection pads 12 denote different transmission signals. In the embodiment of the disclosure, two second connection pads 12 are shown on the base 10.

Next, the process for forming a semiconductor die set may be described with reference to FIGS. 4B to 4D.

In some embodiments, each of the semiconductor die sets may be formed by the following operations. A plurality of first bond pads are formed on a third surface of the first die away from the base. A plurality of second bond pads are formed on a second surface of the second die close to the base. The first die is bonded with the second die through the first bond pads and the second bond pads to form the semiconductor die set.

As shown in FIGS. 4B and 4C, two first bond pads 16 are formed on the third surface C of the first die (die1) away from the base 10. A plurality of second bond pads 17 are formed on the second surface B of the second die (die2) close to the base 10. Both the first bond pads 16 and the second bond pads 17 may be aluminum pads or copper pads.

In some embodiments, before the second bond pads 17 are formed in the second die (die2), the method for forming a semiconductor device further includes forming re-distributed layers 18 on the second surface B of the second die (die2) close to the base 10. The re-distributed layers 18 may be composed of any metallic material, such as copper, aluminum, copper-aluminum alloy or tungsten. The re-distributed layers 18 are configured to electrically connect the second bond pads 17 with the conductive pillars formed subsequently.

In some embodiments, the re-distributed layers are formed in a dielectric layer on the second surface of the second die (die2). The dielectric layer on the surface of the second die (die2) is not shown in FIG. 4C for ease of understanding.

In some embodiments, continuously referring to FIG. 4C, after the re-distributed layers 18 are formed in the second die (die2), the method of forming a semiconductor device further includes forming conductive pillars 15 in the second die (die2).

In some embodiments, the conductive pillars 15 may be formed by the following operations. The second die (die2) is etched perpendicular to the second surface B of the second die (die2) to form through via structures (not shown in FIG. 4C) in the second die (die2). A conductive material is filled in the through via structures. The second die (die2) is thinned along the first surface A of the second die (die2) until the conductive material is exposed, so that the conductive pillars 15 are formed.

In some embodiments, the conductive pillars 15 may also be formed by the following operations. The second die (die2) is etched along the second surface B of the second die (die2) to form through via structures (not shown in FIG. 4C) in the second die (die2). A buffer material, a barrier material and a conductive material are sequentially filled in the through via structures. The second die (die2) is thinned along the first surface A of the second die (die2) until the buffer material, the barrier material and the conductive material are exposed, so that the buffer layers, the barrier layers and the conductive pillars 15 are formed.

The buffer material may be, for example, silicon oxide. The buffer layer is configured to protect the silicon substrate of the second die (die2) from being damaged. The material of the barrier material may be tantalum, tantalum nitride, titanium nitride, or the like. The barrier layer is configured to prevent diffusion of the conductive material subsequent filled in the through via structures. The conductive material may be any conductive metal, for example tungsten, cobalt, copper, aluminum, or the like. For example, the conductive material is copper metal. Specifically, for example, the copper conductive pillars may be formed by the following operations. A copper seed layer is deposited by physical vapor deposition (PVD), and then copper is deposited by electroplating.

In some embodiments, the second die may be thinned by chemical mechanical polishing (CMP) or dry etching until the conductive material is exposed or until the buffer material, the barrier material and the conductive material are exposed.

In the embodiment of the disclosure, through silicon via (TSV) technology can reduce the interconnection length between the dies, reduce signal delay, reduce capacitance or inductance, and thus achieve low power consumption and high-speed communication between the dies.

In some embodiments, continuously referring to FIG. 4C, after the conductive pillars 15 are formed, the method for forming a semiconductor device further includes forming first connection pads 14 on the first surface A of the second die (die2). The first connection pads 14 are electrically connected to the conductive pillars 15. The first connection pads 14 may be aluminum pads, copper pads, tin pads, gold pads or alloy pads.

In some embodiments, the bonding the first die with the second die through the first bond pads and the second bond pads to form the semiconductor die set includes the following operation.

A surface activation treatment is performed on the third surface of the first die and the second surface of the second die.

In the embodiment of the disclosure, a purpose of the activation treatment is to clean the third surface C of the first die (die1) and the second surface B of the second die (die2) to remove metal oxides, chemicals, particles, or other impurities on the third surface C of the first die (die1) and the second surface B of the second die (die2).

In the embodiment of the disclosure, the third surface is attached to the second surface, and each of the first bond pads is aligned face-to-face with the corresponding one of the second bond pads.

In the embodiment of the disclosure, the first die and the second die are annealed to bond the first die with the second die.

In the embodiment of the disclosure, defects in the first die and the second die are reduced by annealing the first die and the second die.

As shown in FIG. 4D, the surface activation treatment is performed on the third surface C of the first die (die1) and the second surface B of the second die (die2). The third surface C is attached to the second surface B. Each of the first bond pads 16 is aligned face-to-face with the corresponding one of the second bond pads 17. The first die (die1) and the second die (die2) are annealed to bond the first die (die 1) with the second die (die2) so as to form the semiconductor die set 131.

In the embodiment of the disclosure, the first die (die1) is boned with the second die (die2) face-to-face, so that the first die (die 1) and the second die (die2) in the semiconductor die set 131 are connected to a same rank (for example Rank0).

In some embodiments, the semiconductor die set 132 formed by bonding the first die (die3) with the second die (die4) face-to-face may also be formed by the above method shown in FIG. 4E.

In the embodiment of the disclosure, after functional devices are formed on the wafer, the wafer is cut to form a single semiconductor dies (die), and then two semiconductor dies (die) are bonded face-to-face to form a semiconductor die set. The two semiconductor dies located in a same semiconductor die set are connected to a same rank. Therefore, the semiconductor die set may also be referred as a single rank particle.

In some embodiments, the electrically connecting the plurality of semiconductor die sets to the base in sequence includes the following operation. Connection structures that connect the first connection pads with the second connection pads are formed in sequence.

The specific process for connecting the semiconductor die sets with the base is described with reference to FIGS. 4F to 4H.

As shown in FIG. 4F, the semiconductor die set 131 is stacked on the base 10. Before the semiconductor die set 131 is stacked on the base 10, an insulating layer 133 is formed to connect the base 10 with the semiconductor die set 131. The insulating layer 133 is configured to electrically isolate the base 10 from the semiconductor die set 131 and to attach the semiconductor die set 131 on the base 10. In the embodiment of the disclosure, the insulating layer 133 may be a DAF film. The DAF film can also be configured to ameliorate the warpage phenomenon of the semiconductor dies.

Next, the semiconductor die set 131 is electrically connected to the base 10, which is specifically implemented as follows: connection structures 191 and connection structures 194 are formed to connect the first connection pads 14 on the semiconductor die set 131 and the second connection pads 12 on the base 10.

Next, as shown in FIG. 4G, a dielectric layer 134 is formed on the surface of the semiconductor die set 131 for electrically isolating the semiconductor die set 131 from the subsequently stacked semiconductor die set 132. In the embodiment of the disclosure, the dielectric layer 134 may be a FOW film. The FOW film can prevent warpage of the semiconductor dies. In addition, because the FOW film has a high hardness, the FOW film is also configured to fix the connection structures 191 connected to the first connection pads on the semiconductor die set 131 and prevent the connection structures 191 and the connection structures 194 from shifting or falling off.

Last, as shown in FIG. 4H, the semiconductor die set 132 is electrically connected to the base 10, which is specifically implemented as follows: connection structures 192 and connection structures 193 are formed to connect the first connection pads 14 on the semiconductor die set 132 and the second connection pads 12 on the base 10.

In the embodiment of the disclosure, by providing through vias (i.e. conductive pillars) in the dies, forming the first connection pads on the back surface of the dies, and providing re-distributed layers and bond pads on the front of the dies, two dies are bonded face-to-face to obtain a semiconductor die set (i.e. a single Rank particle). A plurality of such semiconductor die sets are stacked on the base to form a semiconductor stack structure.

In the embodiment of the disclosure, two dies bonded face-to-face of the semiconductor die set are connected to a same rank, that is, the two dies in the semiconductor die set are electrically connected to the base through a same metal wire, so that the signal transmission of the two dies can be consistent, and thus time delay of the semiconductor device can be reduced.

The semiconductor device formed by the method for forming a semiconductor device provided by the embodiments of the disclosure is similar to the semiconductor device provided by the forgoing embodiments. The technical features not disclosed in detail in the embodiments of the disclosure could be understood with reference to the foregoing embodiments, and the features are not repeated here.

In addition, the embodiments of the disclosure further provide a method for forming a semiconductor device, which includes the following operations. A base is provided; a plurality of semiconductor die sets stacked in sequence along a first direction are formed on a surface of the base. The plurality of semiconductor die sets are respectively connected to different ranks, and the plurality of semiconductor die sets are all electrically connected to the base.

Each of the semiconductor die sets includes a first die and a second die bonded face-to-face, and the first die and the second die are connected to a same rank.

In some embodiments, the forming a plurality of semiconductor die sets stacked in sequence along a first direction on a surface of the base includes the following two operations. The plurality of semiconductor die sets are formed. The plurality of semiconductor die sets are electrically connected to the base in sequence.

FIG. 5 is a flowchart showing a method for forming semiconductor die sets provided by an embodiment of the disclosure. As shown in FIG. 5, the semiconductor die sets are formed by the following operations.

In some embodiments, the semiconductor die sets may also be formed by the following operations.

In S501, a first wafer and a second wafer are provided.

In S502, functional devices are formed on a front surface of the first wafer and a front surface of the second wafer, respectively.

In S503, re-distributed layers are formed on the front surface of the second wafer.

In S504, the second wafer is etched to form through via structures penetrating through part of the second wafer.

In S505, a conductive material is filled in the through via structures, and the second wafer is thinned along a back surface of the second wafer until the conductive material is exposed to form conductive pillars. The conductive pillars are electrically connected to the re-distributed layers.

In S506, first connection pads are formed on the back surface of the second wafer. The first connection pads are electrically connected with the conductive pillars. The back surface of the second wafer and the front surface of the second wafer are two opposite surfaces of the second wafer along a first direction. The first direction is a thickness direction of the second wafer.

In S507, a plurality of second bond pads are formed on the front surface of the second wafer.

In S508, a plurality of first bond pads are formed on the front surface of the first wafer. A projection area of each of the first bond pads coincides with a projection area of a corresponding one of the second bond pads along the first direction.

In S509, the first wafer and the second wafer are bonded face-to-face.

In some embodiments, S509 may include the following operations. The front surface of the first wafer is attached to the front surface of the second wafer, and each of the first bond pads is aligned face-to-face with the corresponding one of the second bond pads. The first wafer and the second wafer are annealed to bond the first wafer and the second wafer face-to-face.

In S510, the bonded first wafer and the second wafer after bonded are cut to form a plurality of semiconductor die sets.

In the embodiment of the disclosure, a single Rank particle (i.e., a semiconductor die set) is formed by bonding at a wafer stage and then cutting the bonded wafers, which can simplify a process for manufacturing the semiconductor die sets, shorten the manufacturing cycle of the semiconductor die sets and save the manufacturing cost of the semiconductor device.

In some embodiments, electrically connecting the plurality of semiconductor die sets to the base in sequence includes the following operation. Connection structures that connect the first connection pads with the second connection pads are formed in sequence.

A specific process for connecting the semiconductor die sets with the base is described as follows.

First, a semiconductor die set is stacked on the base. Before the semiconductor die set is stacked on the base, an insulating layer is formed to connect the base with the semiconductor die set. The insulating layer is configured to electrically isolate the base from the semiconductor die set and attach the semiconductor die set on the base 10. In the embodiment of the disclosure, the insulating layer may be a DAF film. The DAF film can also be configured to ameliorate the war page phenomenon of the semiconductor dies.

Next, the semiconductor die set is electrically connected to the base, which is implemented as follows: connection structures are formed to connect the first connection pads of the semiconductor die set and the second connection pads on the base.

Next, a dielectric layer is formed on the surface of the semiconductor die set for electrically isolating the semiconductor die set from the subsequently stacked semiconductor die set. In the embodiment of the disclosure, the dielectric layer may be a FOW film. The FOW film can prevent warpage of the semiconductor dies. In addition, because the FOW film has high hardness, the FOW film is also configured to fix the connection structures connected to the first connection pads on the semiconductor die set and prevent the connection structures from shifting or falling off.

Finally, the semiconductor die set is electrically connected to the base, which is implemented as follows: connection structures are formed to connect the first connection pads of the semiconductor die set and the second connection pads on the base.

In the embodiment of the disclosure, by providing through vias (i.e. conductive pillars) in each of the dies of the wafer, forming the first connection pads on the back surface of each of the dies of the wafer, and providing re-distributed layers and bond pads on the front surface of each of the dies of the wafer, two wafers are bonded face-to-face, and the bonded two wafers are cut to obtain a plurality of semiconductor die sets (i.e. a plurality of single Rank particles). A plurality of such semiconductor die sets are stacked on the base to form a semiconductor stack structure. In the semiconductor stack structure, the two dies bonded face-to-face in each of the semiconductor die sets are connected to a same rank, that is, the two dies in the same semiconductor die set are electrically connected to the base through a same metal wire, so that the signal transmission of the two dies can be consistent, and thus the time delay of the formed semiconductor device can be reduced.

In several embodiments provided by the disclosure, it is to be understood that the disclosed devices and methods may be implemented in a non-target way. The embodiments of the device described above are only illustrative. For example, the division of the unit is only a logical function division, and there may be another division mode in actual implementation, such as: multiple units or components can be combined, or integrated into another system, or some features can be ignored or not executed. In addition, the components shown or discussed are coupled, or directly coupled with each other.

The features disclosed in the several embodiments of methods or devices provided by the disclosure can be arbitrarily combined without conflict, in order to obtain a new embodiment of a method or of a device.

The above-mentioned are only some embodiments of the disclosure, and the protection scope of the disclosure is not limited thereto. Any change and replacement is easily to think within the technical scope of the embodiments of the disclosure by those skilled in the art, and fall within the protection scope of the disclosure. Therefore, the protection scope of the disclosure shall be subject to the protection scope of the claims.

### INDUSTRIAL PRACTICALITY

The embodiments of the disclosure provide a semiconductor device and a method for forming the same. The semiconductor device includes the plurality of semiconductor die sets electrically connected to the base, and each of the semiconductor die sets includes a first die and a second die bonded face-to-face. Since the first die and the second die are connected to a same rank, the signal transmission times and phases of the first die and the second die can be consistent, and the performance of the semiconductor device can be improved. In addition, in the embodiments of the disclosure, winding is not required when the semiconductor die sets (i.e., the first die and the second die) are electrically connected to the base, so that the number of stacking layers of the semiconductor device can be increased and the integration density of the semiconductor device can be improved.

1. A semiconductor device, comprising:
a base; and
a plurality of semiconductor die sets located on a surface of the base and stacked in sequence along a first direction, the plurality of semiconductor die sets being respectively connected to different ranks, and the plurality of semiconductor die sets being all electrically connected to the base, and the first direction being a thickness direction of the base;
wherein each of the plurality of semiconductor die sets comprises a first die and a second die bonded face-to-face, and the first die and the second die are connected to a same rank.

2. The semiconductor device of claim 1, wherein, the semiconductor device further comprises a first connection pad located on a first surface of the second die away from the base along the first direction, the second die comprises a conductive pillar,
wherein the first connection pad is electrically connected to the conductive pillar, and the conductive pillar penetrates through the second die.

3. The semiconductor device of claim 2, wherein the first die comprises a plurality of first bond pads arranged at intervals, and the plurality of first bond pads are located on a third surface of the first die away from the base along the first direction,
the second die further comprises a plurality of second bond pads arranged at intervals, the plurality of second bond pads are located on a second surface of the second die close to the base along the first direction; and
a projection area of each of the plurality of first bond pads coincides with a projection area of a corresponding one of the plurality of second bond pads along the first direction, and each of the plurality of first bond pads is electrically connected to the corresponding one of the plurality of second bond pads.

4. The semiconductor device of claim 3, wherein the second die further comprises a re-distributed layer located on the second surface, and configured to connect the second bond pad with the conductive pillar.

5. The semiconductor device of claim 2, further comprising: a second connection pad located on the surface of the base;
wherein each of the plurality of semiconductor die sets is electrically connected to the base through the first connection pad and the second connection pad.

6. The semiconductor device of claim 5, further comprising connection structures;
wherein each of the connection structures is configured to connect the first connection pad and the second connection pad.

7. The semiconductor device of claim 6, further comprising an insulating layer located between the plurality of semiconductor die sets and the base, and a dielectric layer located between two adjacent ones of the plurality of semiconductor die sets.

8. The semiconductor device of claim 7, further comprising a plurality of semiconductor die sets arranged in sequence along a second direction, the second direction being any direction in a plane on which the base is located.

9. The semiconductor device of claim 8, further comprising a plastic packaging layer covering at least the plurality of semiconductor die sets and the base;
wherein the base further comprises connection solder balls, the connection solder balls and the second connection pads are respectively located on two surfaces of the base along the first direction.

10. A method for forming a semiconductor device, comprising:
providing a base; and
forming a plurality of semiconductor die sets stacked in sequence along a first direction on a surface of the base, the plurality of semiconductor die sets being respectively connected to different ranks, and the plurality of semiconductor die sets being all electrically connected to the base, and the first direction being a thickness direction of the base; each of the semiconductor die sets comprising a first die and a second die bonded face-to-face, and the first die and the second die being connected to a same rank.

11. The method of claim 10, wherein forming a plurality of semiconductor die sets stacked in sequence along a first direction on a surface of the base comprises:
forming the plurality of semiconductor die sets; and
electrically connecting the plurality of semiconductor die sets to the base in sequence.

12. The method of claim 11, wherein forming each of a plurality of semiconductor die sets comprises:
forming a plurality of first bond pads on a third surface of the first die away from the base;
forming a plurality of second bond pads on a second surface of the second die close to the base; and
bonding the first die with the second die through the first bond pads and the second bond pads to form each of the plurality of semiconductor die sets.

13. The method of claim 12, wherein bonding the first die with the second die through the first bond pads and the second bond pads to form each of the plurality of semiconductor die sets comprises:
performing a surface activation treatment on the third surface of the first die and the second surface of the second die;
attaching the third surface to the second surface, and aligning each of the first bond pads face-to-face with a corresponding one of the second bond pads; and
annealing the first die and the second die to bond the first die with the second die.

14. The method of claim 13, before bonding the first die with the second die, further comprising:
forming a through via structure penetrating through part of the second die in the second die;
filling a conductive material in the through via structure; and
thinning the second die along a first surface of the second die until the conductive material is exposed to form a conductive pillar.

15. The method of claim 14, further comprising:
forming a first connection pad on the first surface of the second die away from the base after forming the conductive pillar, wherein the first connection pad is electrically connected to the conductive pillar.

16. The method of claim 15, further comprising:
forming a re-distributed layer on the second surface of the second die before the forming the second bond pads and the conductive pillars, wherein the re-distributed layer is connected to the second bond pads and the conductive pillar respectively.

17. The method of claim 16, wherein the base is formed with a second connection pad, and the method further comprising:
forming connection structures in sequence, each of the connection structures connecting the first connection pad to the second connection pad to electrically connect each of the plurality of semiconductor die sets with the base.

18. The method of claim 10, further comprising:
forming an insulating layer connecting the base and the plurality of semiconductor die sets.

19. The method of claim 18, further comprising:
forming a dielectric layer connecting two adjacent ones of the plurality of semiconductor die sets.
